(19) United States
(12) Patent Application Publication
(10) Pub. No.: US 2012/0153311 A1
(43) Pub. Date: Jun. 21, 2012

(54) LOW-COST SOLID-STATE BASED LIGHT EMITTING DEVICES WITH PHOTOLUMINESCENT WAVELENGTH CONVERSION AND THEIR METHOD OF MANUFACTURE

(75) Inventors: Xianglong Yuan, Fremont, CA (US); Bing Dai, Fremont, CA (US); Charles Edwards, Pleasanton, CA (US)

(73) Assignee: INTEMATIX CORPORATION, Fremont, CA (US)

(21) Appl. No.: 13/324,309

(22) Filed: Dec. 13, 2011

Related U.S. Application Data
(60) Provisional application No. 61/424,589, filed on Dec. 17, 2010.

(51) Int. Cl. H01L 25/13; B29D 11/00; B05D 5/06; B05D 5/12; H01L 33/50; F21V 9/16

(52) U.S. Cl. 257/88; 438/27; 362/84; 427/64; 264/2.7; 257/E25.028; 257/E33.061

(57) ABSTRACT

A method of manufacturing a light emitting device comprises: mounting and electrically connecting a plurality of solid-state light emitters onto a substrate in a known configuration; screen printing a pattern of at least one photo luminescent material onto a surface of a light transmissive carrier such that there is a respective region of photo luminescent material corresponding to a respective one of the light emitters and mounting the carrier to the substrate such that each region of photo luminescent material overlays a respective one of the light emitters. Where the light transmissive carrier comprises a thermo formable material the method can further comprise heating and vacuum molding the carrier such as to form an array of hollow features configured such that a respective feature corresponds to a respective light emitter and is capable of housing a respective light emitter.

### CLAIM OF PRIORITY

This application claims the benefit of priority to U.S. Provisional Patent Application No. 61/424,589, filed Dec. 17, 2010 entitled “Low-Cost LED-Based Light Emitting Devices with Phosphor Wavelength Conversion and their Method of Manufacture”, by Yuan et al., the specification and drawings of which are incorporated in their entirety herein by reference.

### BACKGROUND OF THE INVENTION

1. Field of the Invention

This invention relates to low-cost solid-state based light emitting devices with photo luminescent wavelength conversion and their method of manufacture. More particularly, although not exclusively, embodiments of the invention concern LED (Light Emitting Diode) based devices that utilize a phosphor material to perform wavelength conversion by a process of photoluminescence. The invention further concerns a method of manufacturing a photo luminescent wavelength conversion component.

2. Description of the Related Art

White light emitting LEDs (“white LEDs”) are known and are a relatively recent innovation. It was not until LEDs emitting in the blue/ultraviolet part of the electromagnetic spectrum were developed that it became practical to develop white light sources based on LEDs. As taught, for example in U.S. Pat. No. 5,998,925, white LEDs include one or more phosphor materials, that is photo luminescent materials, which absorb a portion of the radiation emitted by the LED and re-emit light of a different color (wavelength). Typically, the LED chip or die generates blue light and the phosphor(s) absorbs a percentage of the blue light and re-emits yellow light or a combination of green and red light, green and yellow light, green and orange or yellow and red light. The portion of the blue light generated by the LED that is not absorbed by the phosphor material combined with the light emitted by the phosphor provides light which appears to the eye as being nearly white in color.

Due to their long operating life expectancy (>50,000 hours) and high luminous efficacy (70 lumens per watt and higher) high brightness white LEDs are increasingly being used to replace conventional fluorescent, compact fluorescent and incandescent light sources.

An example of a typical white LED 10 is shown in FIG. 1 and comprises a number of blue light emitting GaN (gallium nitride) LED chips 12 housed within a package 14. The package 14, which can for example comprise a low temperature co-fired ceramic (LTCC) or high temperature polymer, comprises upper and lower body parts 16, 18. The upper body part 16 defines a number of recesses 20, often circular in shape, which are configured to receive one or more LED chips 12. The package 14 further comprises electrical connectors 22, 24 that also define corresponding electrode contact pads 26, 28 on the floor of the recess 20. Using adhesive or soldering the LED chips 12 are mounted to the floor of the recess 20. The LED chip's electrode pads are electrically connected to corresponding electrode contact pads 26, 28 on the floor of the package using bond wires 30, 32 and each of the recesses 20 is completely filled with a transparent polymer material 34, typically a silicone, which is loaded with the powdered phosphor material(s) such that the exposed surfaces of the LED chips 12 are covered by the phosphor/polymer material mixture. To enhance the emission brightness of the device the walls of the recess are inclined and have a light reflective surface.

Whilst such devices provide a good performance their cost makes them too expensive for many applications such as general lighting. A need exists for LED-based light emitting devices with phosphor wavelength conversion that are less expensive to manufacture than the prior art solutions.

### SUMMARY OF THE INVENTION

Embodiments of the invention concern solid-state based light emitting devices comprising a plurality of solid-state light emitters, typically LEDs, mounted on a substrate, such as for example a printed circuit board. The light emitters are configured as a known array such as for example a linear, a rectangular, a square, a hexagonal or a circular array. The devices further comprise a separate photo luminescent wavelength conversion component that is positioned on the substrate and is operable to give a desired emission color by converting at least a proportion of the light emitted by the solid-state emitters to light of a different wavelength (color). The wavelength conversion component comprises a light transmissive carrier having a respective region of photo luminescent material that is located such as to overlay a respective one of the light emitters.

In accordance with the invention the wavelength conversion component is manufactured by printing, preferably screen printing, the pattern of photo luminescent material regions onto a surface of the light transmissive carrier. When screen printing the photo luminescent material, the light transmissive carrier typically comprises a substantial planar sheet of light transmissive material. Embodiments of the invention find particular application where the photo luminescent material comprises a phosphor material. However, the invention is applicable to other types of photo luminescent materials, such as quantum dots. A quantum dot is a portion of matter (e.g. semiconductor) whose excitons are confined in all three spatial dimensions that may be excited by radiation energy to emit light of a particular wavelength or range of wavelengths. The wavelength of the photoluminescence generated light is determined by the physical size of the quantum dot.

Where the photo luminescent material comprises a phosphor material this is typically in powder form and can be mixed with a light transmissive liquid binder to form a slurry, “phosphor ink”, which is then printed as a pattern onto the light transmissive carrier. A particular advantage of the invention is the saving in photo luminescent material since photo luminescent material is provided only at regions corresponding to a light emitter.

In one arrangement the device comprises a plate having an array of through holes in which each hole corresponds with one of the light emitters. The holes are configured such that when the plate is mounted to the substrate each hole in conjunction with the substrate defines a shallow cavity housing the light emitter. For such devices the wavelength conversion component can be positioned on the plate such that each photo luminescent material region overlays and covers a respective cavity opening.

In other arrangements the wavelength conversion component can comprise an array of hollow features, such as for example dome shaped shells that are configured such that when the wavelength conversion component is mounted to the substrate each hollow feature encloses and houses a respective one of the light emitters. In such arrangements the phosphor regions are provided at locations corresponding to the location of a respective hollow feature, typically covering the inner concave surface. A benefit of such an arrangement is that the photo luminescent material region is in spaced relation to its associated light emitter that is the photo luminescent material is “remote” to the light emitter. Providing the photo luminescent material remotely can reduce heat transfer to and thermal degradation of the photo luminescent material. In accordance with the invention such a wavelength component can be manufactured using a thermoplastic light transmissive material. The array of photo luminescent material regions can be printed onto the face of the sheet and the sheet can then be heated and vacuum molded to form the array of hollow features. To reduce costs it is preferred to fabricate a large number of wavelength conversion components on a single sheet of material and then divide the sheet into individual wavelength conversion components.

According to an aspect of the invention a method of manufacturing a light emitting device comprises: providing a substrate and a plurality of solid-state light emitters; mounting and electrically connecting the light emitters on the substrate in a known configuration; providing a light transmissive carrier; screen printing a pattern of at least one photo luminescent material onto a surface of the carrier such that there is a respective region of photo luminescent material corresponding to a respective one of the light emitters; positioning the carrier on the substrate such that each photo luminescent material region overlays a respective one of the light emitters. The substrate can comprise a metal cored printed circuit board, a fire retardant printed circuit board or a ceramic circuit board. Advantageously the light emitters are configured as a linear array, a square array, a rectangular array, a hexagonal array or a circular array.

In one embodiment of the invention the method further comprises: providing a plate having an array of through holes and wherein the array of through holes corresponds to the known array of light emitters; positioning the plate on the substrate such that each light emitter is housed within a respective through hole; and positioning the carrier on the plate such that each photo luminescent material region overlays a respective one of the through holes. The plate preferably comprises an opaque material to prevent light escaping from the device and can comprise a printed circuit board, a glass fiber reinforced board, a ceramic plate, a metal plate or a plastics material. The light transmissive carrier can comprise a light transmissive polymer such as a polycarbonate, an acrylic or a polyethylene terephthalate or a glass.

In a further embodiment the light transmissive carrier comprises a thermo formable materials such as a polycarbonate, an acrylic or a polyethylene terephthalate and the method further comprises: heating and molding the carrier such as to form an array of hollow features configured such that a respective feature corresponds to a respective light emitter and is capable of housing a respective light emitter; and mounting the carrier to the substrate such that each light emitter is housed within a hollow feature. Molding the hollow features eliminates the need for the plate and can reduce cost. Preferably the respective regions of the at least one photo luminescent material are printed such that when the features are molded the photo luminescent material covers substantially the inner surface of the feature. The hollow features can be dome shaped, hemispherical shell shaped, parabloidal shell shaped or cylindrical shell shaped.

The method of the invention can further comprise filling each hollow feature with a light transmissive material such as a liquid silicone, acrylic or epoxy material. Such a material provides protection of the light emitters and assists in coupling light from the light emitter into the wavelength conversion component. The hollow features can be filled with the light transmissive adhesive prior to mounting the wavelength conversion component to the substrate or filled after mounting the wavelength conversion component to the substrate. To assist in filling the hollow features and/or enable the escape of excess material one or more channels can be molded into the component.

According to another aspect of the invention a method of manufacturing a wavelength conversion component for a light emitting device of a type comprising a plurality of solid-state light emitters mounted on a substrate in a known configuration; comprises: providing a light transmissive carrier and screen printing a pattern of at least one photo luminescent material onto a surface of the carrier such that there is a respective region of photo luminescent material corresponding to a respective one of the light emitters. The light transmissive carrier can comprise a light transmissive polymer such as a polycarbonate, an acrylic or a polyethylene terephthalate or a glass.

Where the light transmissive carrier comprises a thermo formable material such as a polycarbonate, an acrylic or a polyethylene terephthalate the method can further comprise: heating and vacuum molding the carrier such as to form an array of hollow features configured such that there is a respective feature corresponding to a respective light emitter and each featured is capable of housing a respective light emitter. In one method the respective regions of the at least one photo luminescent material are printed such that when the features are vacuum molded the photo luminescent material covers substantially the inner surface of the feature. The hollow features can be dome shaped, hemispherical shell shaped, parabloidal shell shaped or cylindrical shell shaped.

To further reduce manufacturing costs the method advantageously comprises manufacturing a plurality of wavelength conversion components on a sheet and dividing the sheet into separate components.

The pattern of printed photo luminescent material regions corresponds to the known configuration and can be a linear array, a square array, a rectangular array, a hexagonal array or a circular array.

According to a further aspect of the invention a light emitting device comprises: a substrate; a plurality of solid-state light emitters mounted on, and electrically connected to, the substrate in a known configuration; and a wavelength conversion component comprising at least one photo luminescent material and operable to absorb a portion of light emitted by the light emitters and emit light of a different wavelength, wherein the emission product of the device comprises a combination of light generated by the light emitters and the at least one photo luminescent material, and wherein the wavelength conversion component comprises a light transmissive carrier having a pattern of the at least one photo luminescent material on a surface of the carrier and configured such that there is a respective region of photo luminescent material corresponding to a respective one of the light emitters. The light transmissive carrier can comprise a light transmissive polymer such as a polycarbonate, an acrylic or a polyethylene terephthalate or a glass.

In one arrangement the device further comprises a plate having an array of through holes that are configured as the known array and are capable of housing a respective light emitters and wherein the wavelength conversion component is mounted to the plate such that each photo luminescent material region overlays a respective one of the through holes.

Alternatively the wavelength conversion component comprises an array of hollow features molded in the carrier that are configured such that a respective feature corresponds to a respective light emitter and is capable of housing a respective light emitter. Preferably in such components each region of the at least one photo luminescent material covers substantially the inner surface of a respective feature. The hollow features can be dome shaped, hemispherical shell shaped, parabloidal shell shaped or cylindrical shell shaped.

The solid-state light emitters can be configured as a linear array, a square array, a rectangular array, a hexagonal array or a circular array.

Depending on the light emitter geometry they can be electrically connected to the substrate by wire bonding. Alternatively the light emitters can be mounted on, and electrically connected to, the substrate using flip chip bonding.

The substrate can comprise a metal cored printed circuit board, a fire retardant printed circuit board or a ceramic circuit board.

### BRIEF DESCRIPTION OF THE DRAWINGS

In order that the present invention is better understood solid-state based light emitting devices in accordance with embodiments of the invention and their method of manufacture will now be described, by way of example only, with reference to the accompanying drawings in which:

FIG. 1 is a schematic sectional view of a known LED-based light emitting device as previously described;

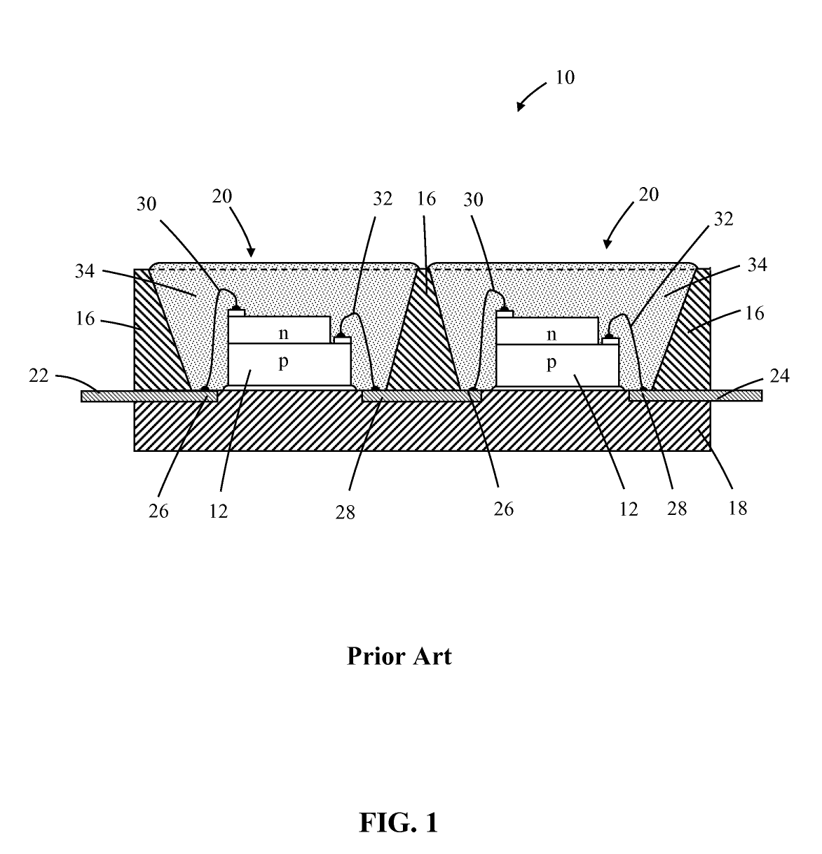

FIG. 2 is a schematic plan view of an LED-based light emitting device in accordance with an embodiment of the invention;

FIG. 3 is an exploded sectional view of the light emitting device of FIG. 2 through A-A;

FIG. 4 is an enlarged sectional view showing a part of the device of FIG. 3;

FIG. 5 shows schematic plan and sectional views of an LED-based light emitting device in accordance with an embodiment of the invention;

FIGS. 6a to 6n are schematic representations illustrating the steps for manufacturing the light emitting devices of FIGS. 2 to 5;

FIG. 7 shows schematic plan, sectional and end views of a photo luminescent wavelength conversion component in accordance with an embodiment of the invention;

FIG. 8 is a schematic partial sectional plan view of an LED-based light emitting device in accordance with an embodiment of the invention;

FIG. 9 is an sectional view of the light emitting device of FIG. 8 through A-A;

FIG. 10 is an exploded sectional view of the light emitting device of FIG. 8 through A-A;

FIG. 11 is a sectional view of the light emitting device in accordance with an embodiment of the invention; and

FIG. 12 is an enlarged sectional view showing a part of the device in accordance with an embodiment of the invention.

### DETAILED DESCRIPTION OF THE INVENTION

Throughout this patent specification like reference numerals are used to denote like parts.

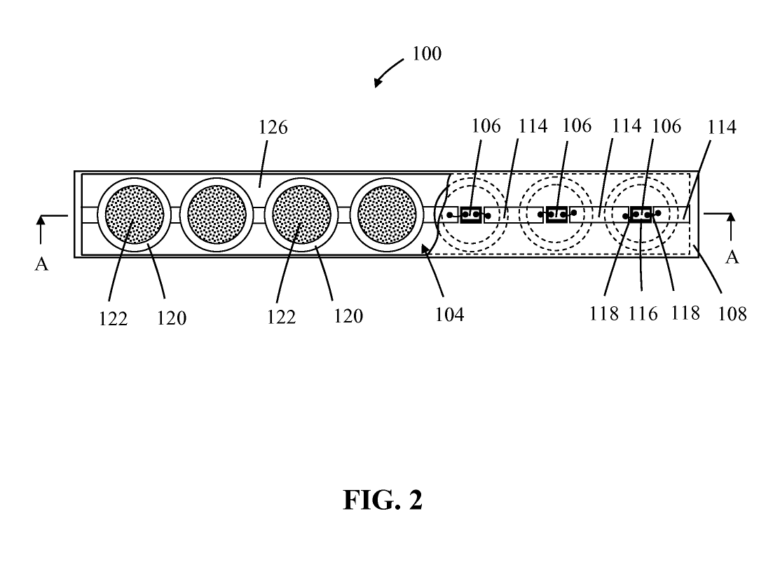

A low-cost solid-state based light emitting device 100 in accordance with an embodiment of the invention is now described with reference to FIGS. 2, 3 and 4 which respectively show a schematic plan, an exploded sectional and an enlarged sectional schematic of a part of the device. The device 100 can be configured to generate white light with a correlated color temperature (CCT) of 2700K.

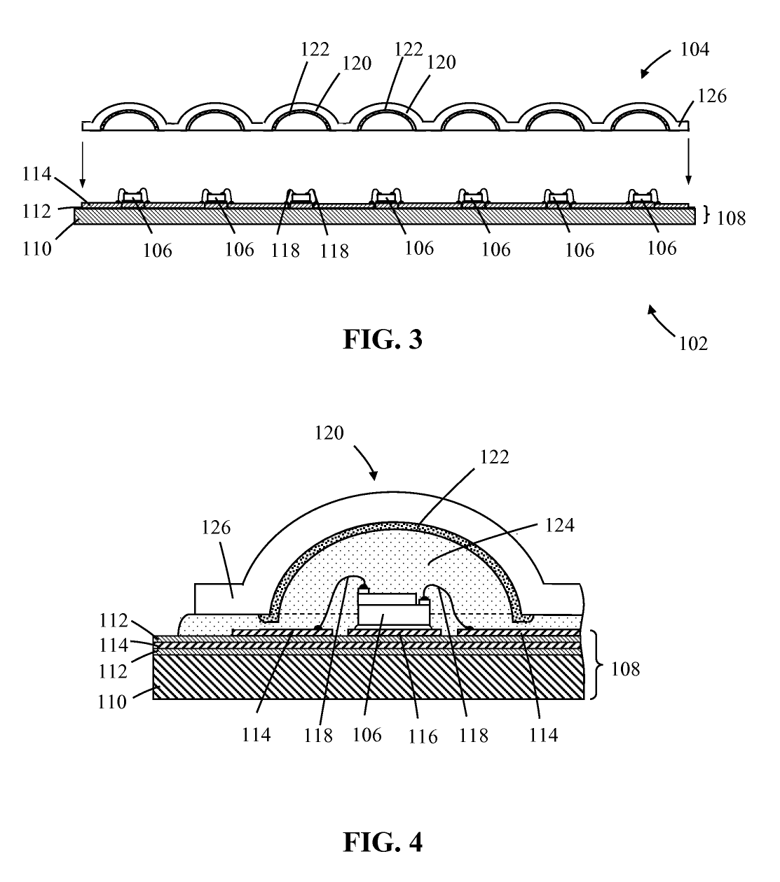

As is best seen in FIG. 3 the device 100 comprises an assembly composed of a solid-state light engine 102 and a photo luminescent wavelength conversion component 104. The light engine 102 comprises a plurality of blue (i.e. peak wavelength ≈400 to 480 nm) surface emitting InGaN/GaN (indium gallium nitride/gallium nitride) based LED chips 106 that are mounted in a known configuration on a substrate 108 such as for example a metal core printed circuit board (MCPCB)—a so called chip on board (COB) arrangement. In other arrangements it is envisioned that the substrate 108 comprise a printed circuit board such as an FR-4 (fire retardant 4) printed circuit board or a ceramic circuit board. As is known MCPCBs are commonly used for mounting electrical components that generate large amounts of heat and comprise a layered structure comprising a thermally conducting base 110, typically a metal such as aluminum (Al), and alternating layers of an electrically non-conducting/thermally conducting dielectric material 112 and electrically conducting tracks 114, typically made of copper (Cu). The dielectric layers 112 are very thin such that they can conduct heat from components mounted on the electrical tracks to the base 110. The electrically conducting tracks 114 are configured to define an electrical circuit for electrically connecting and providing electrical power to the array of LED chips 106. The electrically conducting tracks 114 can further define thermally conductive mounting pads 116 on which the LED chips can be mounted using a thermally conductive adhesive or soldering. Each of The LED chips 106 is electrically connected to the conducting tracks by a pair of bond wires 118. Depending on the LED chip architecture the LED chips 106 can alternatively be flip chip bonded to the MCPCB 108.

In the exemplary embodiment of FIGS. 2 and 3 the LED chips 106 are configured as a linear array of six LED chips 106 and the conducting tracks 114 configured such that the six LED chips 106 are serially connected as a string. It will be appreciated that devices of the invention can comprise other LED chip configurations such as for example square, rectangular, hexagonal or circular arrays.

The photo luminescent wavelength conversion component 104 comprises a light transmissive carrier 126 and can be fabricated from a light transmissive thermo formable plastics (thermoplastic) material such as a polycarbonate, an acrylic—poly(methyl methacrylate) (PMMA) or a PET (Polyethylene terephthalate). In FIG. 2 a right hand portion of the wavelength conversion component 104 is cut away to reveal the LED chips 106 and conducting tracks 114. As indicated by a dashed line in FIG. 2 the wavelength conversion component 104 has a footprint that corresponds to and substantially covers the substrate 108. The wavelength conversion component 104 comprises a linear array of dome (generally hemispherical) shaped shells 120 that are configured such that when the component is mounted to the substrate 108 each dome 120 overlays and encloses a respective one of the LED chips 106. A photo luminescent wavelength conversion layer 122 comprising one or more blue light excitable photo luminescent materials is provided over the inner concave surface of each dome 120. In operation the photo luminescent wavelength conversion layer 122 absorbs a portion of the blue light generated by its associated LED chip and through a process of photoluminescence emits light of a different color (wavelength) typically yellow-green. The emission product of the device comprises the combination of blue light generated by the LED chips and photoluminescence light generated by the photo luminescent conversion layer 122. Typically the photo luminescent material(s) is selected such that the emission product of the device appears white in color.

The photo luminescent material can comprise a phosphor material or a quantum dot. A quantum dot is a portion of matter (e.g. semiconductor) whose excitons are confined in all three spatial dimensions that may be excited by radiation energy to emit light of a particular wavelength or range of wavelengths that is determined by the physical size of the quantum dot. As such, the invention is not limited to phosphor based wavelength conversion components unless claimed as such.

When the photo luminescent material comprises a phosphor it can comprise an inorganic or organic phosphor such as for example silicate-based phosphor of a general composition A₃Si(O,D)₅ or A₂Si(O,D)₄ in which Si is silicon, O is oxygen, A comprises strontium (Sr), barium (Ba), magnesium (Mg) or calcium (Ca) and D comprises chlorine (Cl), fluorine (F), nitrogen (N) or sulfur (S). Examples of silicate-based phosphors are disclosed in U.S. Pat. No. 7,575,697 B2 “Silicate-based green phosphors” (assigned to Intematix Corporation), U.S. Pat. No. 7,601,276 B2 “Two phase silicate-based yellow phosphors” (assigned to Intematix Corporation), U.S. Pat. No. 7,655,156 B2 “Silicate-based orange phosphors” (assigned to Intematix Corporation) and U.S. Pat. No. 7,311,858 B2 “Silicate-based yellow-green phosphors” (assigned to Intematix Corporation). The phosphor can also comprise an aluminate-based material such as is taught in our co-pending patent application US2006/0158090 A1 “Novel aluminate-based green phosphors” and patent U.S. Pat. No. 7,390,437 B2 “Aluminate-based blue phosphors” (assigned to Intematix Corporation), an aluminum-silicate phosphor as taught in co-pending application US2008/0111472 A1 “Aluminum-silicate orange-red phosphor” or a nitride-based red phosphor material such as is taught in our co-pending United States patent application US2009/0283721 A1 “Nitride-based red phosphors” and International patent application WO2010/074963 A1 “Nitride-based red-emitting in RGB (red-green-blue) lighting systems”. It will be appreciated that the phosphor material is not limited to the examples described and can comprise any phosphor material including nitride and/or sulfate phosphor materials, oxy-nitrides and oxy-sulfate phosphors or garnet materials (YAG).

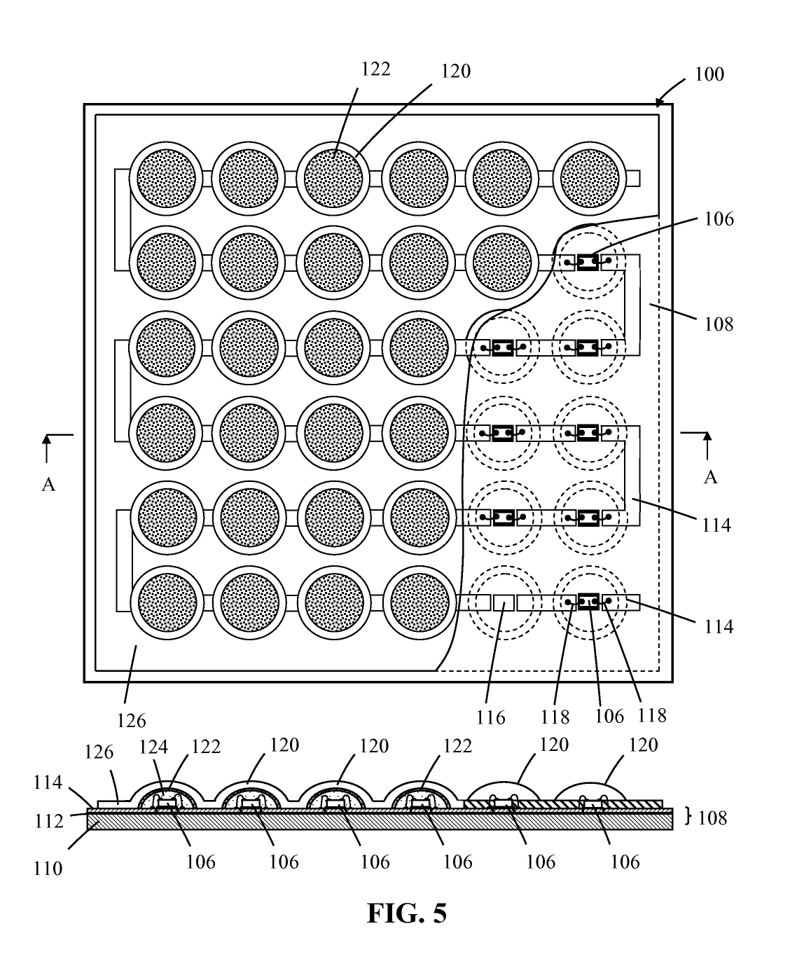

The photo luminescent wavelength conversion component 104 can be bonded to the substrate 108 using a light transmissive adhesive 124, typically a polymer such as an acrylic, silicone or an epoxy. As indicated in FIG. 4 and to provide protection of the LED chip 106 and bond wires 118 each dome 120 can optionally be completely filled with a light transmissive material such as the light transmissive adhesive 124. Advantageously, the light transmissive material is selected such that its refractive index is as close to the refractive index of the LED chips 106 as practicable. For example, the refractive index of an InGaN/GaN LED chip is n≈2.4 to 2.5 whilst a high refractive index silicone has a refractive index n≈1.2 to 1.5. Thus in practice the polymer material 124 has a refractive index ≧1.2. The use of a high refractive polymer can increase emission of light from the LED chips 106 by providing a degree of refractive index matching.

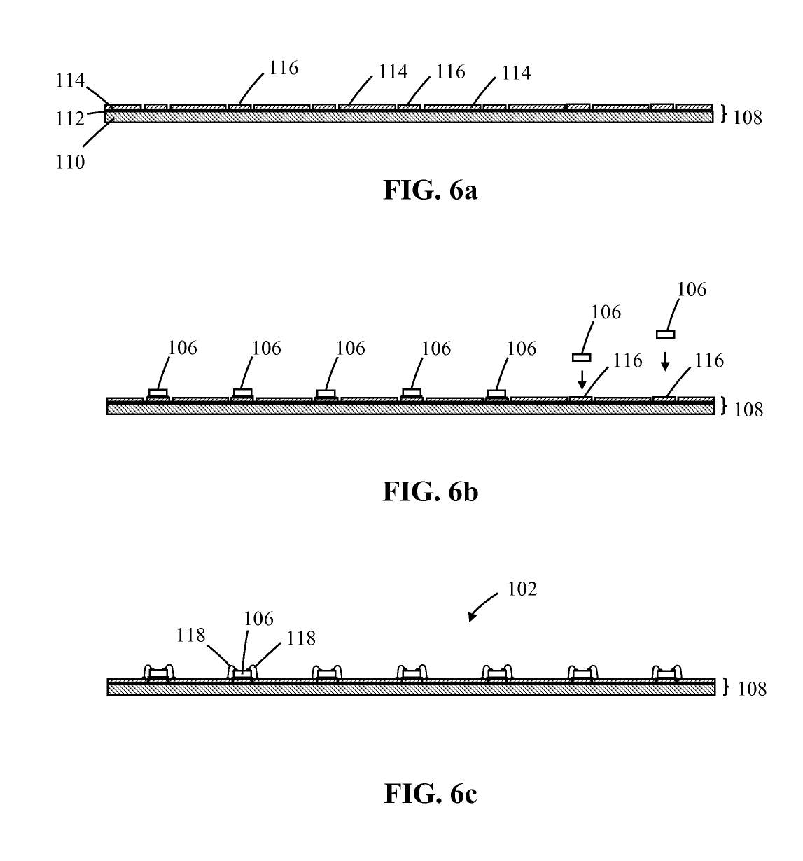

FIG. 5 shows schematic plan and sectional views of an LED-based light emitting device in accordance with an embodiment of the invention. In this embodiment thirty six LED chips 106 are configured as a square array six rows by six columns on a MCPCB 108. In accordance with the invention the photo luminescent wavelength conversion component 104 comprises a matching array of domes 120 that include a photo luminescent material layer on their inner surface.

Manufacture of Light Emitting Devices in Accordance with Invention

A method of manufacturing the light emitting device of FIGS. 2, 3 and 4 is now described with reference to FIGS. 5a to 5n. As described above the light emitting devices of the invention comprise an assembly of the solid-state light engine 102 and a photo luminescent wavelength conversion component 104 the method of manufacture of each of which is now described.

Manufacture of Solid-State Light Engine (FIGS. 5a and 5c)

The LED chips 106 are mounted on the substrate 108, by for example soldering, as a known array (FIGS. 5a and 5b). Each of the LED chips 106 is electrically connected to the substrate 108 by for example wire bonding 118. Alternatively the LED chips 106 can be bonded and electrically connected to the substrate by flip chip bonding.

Manufacture of Photo Luminescent Wavelength Conversion Component (FIGS. 5d to 5k)

The method of manufacture of the photo luminescent wavelength conversion component 104 is now described with reference to FIGS. 5d to 5k. The wavelength conversion component 104 starts life as a light transmissive carrier in the form of a sheet 126 of a light transmissive thermo formable polymer material such as a polycarbonate, an acrylic-poly(methyl methacrylate) (PMMA) or a PET (Polyethylene terephthalate). An example of a suitable material is General Electric Plastics' Lexan® 8010 (U.V. stabilized) polycarbonate film (0.020 inch thick). Since the present invention concerns the manufacture of low-cost devices the wavelength conversion components are typically mass produced from a single sheet. For example approximately three hundred wavelength components (100 mm by 15 mm) can be fabricated from a single sheet 126 1000 mm by 500 mm. For ease of understanding only fabrication of a single component is illustrated in the figures.

### Printing of Photo Luminescent Wavelength Conversion Layer:

The photo luminescent wavelength conversion layer 122 can be screen printed on the carrier sheet 126 using a photoluminescent composition 132 comprising a slurry of the powdered photo luminescent material(s) and a light transmissive liquid binder material. Since the photoluminescent composition is printable it will in this specification and for the sake of brevity, is referred to as “phosphor ink”. The binder material can comprise a curable liquid polymer such as a polymer resin, a monomer resin, an acrylic, an epoxy (polyepoxide), a silicone, a fluorinated polymer or a clear screen printable ink. It is important that the binder material is, in its cured state, transmissive to all wavelengths of light generated by the photo luminescent (phosphor) material(s) and the LED chips 106 and preferably has a transmittance of at least 0.9 over the visible spectrum (380 to 800 nm). The binder material is preferably U.V. curable though it can be thermally curable, solvent based or a combination thereof. U.V. or thermally curable binders can be preferable because, unlike solvent-based materials, they do not “outgas” during polymerization. When a solvent evaporates the volume and viscosity of the composition will change resulting in a higher concentration of photo luminescent material which will affect the emission product color of the device. With U.V. curable polymers, the viscosity and solids ratios are more stable during the deposition process with U.V. curing used as to polymerize and solidify the layer after deposition is completed. Moreover since in the case of screen printing of the phosphor ink multiple-pass printing may be required to achieve a required layer thickness, the use of a U.V. curable binder is preferred since each layer can be cured virtually immediately after printing prior to printing of the next layer.

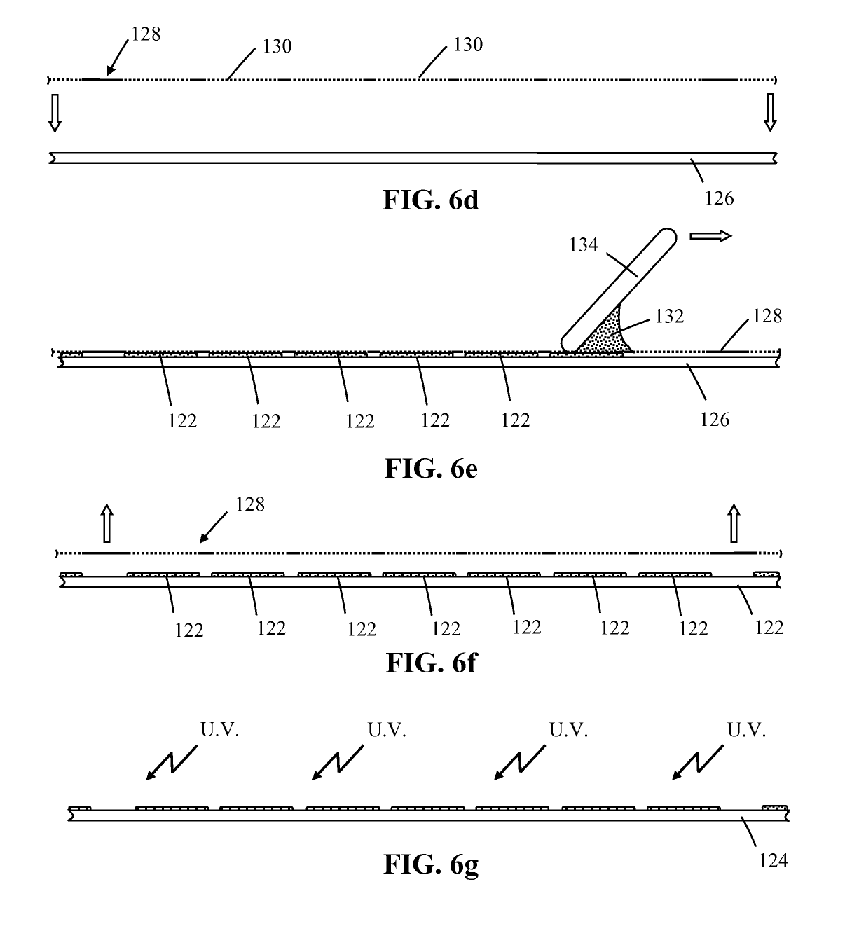

As shown in FIG. 6d a print screen 128 is positioned over the sheet 126. The screen 128 comprises a pattern of openings 130 that are configured to print a respective region of photo luminescent material corresponding to each LED chip 106. In this example the print screen 128 has apertures 130 that define a linear array of seven circular regions. The phosphor ink 132 is printed onto the sheet 126 by drawing the phosphor ink 132 over the print screen 128 using a flexible blade (squeegee) 134 (FIG. 6e). The print screen 128 is removed from the sheet 126 (FIG. 5f) and the printed phosphor ink 132 cured by exposing the sheet 126 to U.V. light (FIG. 5g). Typically the phosphor ink is cured by placing the sheet on a conveyor that passes through a U.V. curing station.

The color of the emission product produced by the device will depend on the quantity of photo luminescent material per unit area in the wavelength conversion layer 122. It will be appreciated that the quantity of photo luminescent material per unit area is dependent on the thickness of the wavelength conversion layer 122 and the weight loading of photo luminescent material to binder in the phosphor ink. In applications in which the emission product is white or in applications in which the emission product has a high saturation color (i.e. the emission product comprises substantially all photo luminescence generated light) the quantity of photo luminescent material per unit area in the wavelength conversion layer 122 will typically be between 10 mg.cm⁻² and 40 mg.cm⁻². To enable printing of the wavelength conversion layer 122 in a minimum number of print passes the phosphor ink 132 preferably has as high a solids loading of phosphor (photo luminescent) material to binder material as possible and preferably has a weight loading of phosphor material to binder is as high as possible and is preferably in a range 40% to 75%. It has been found that above about a 75% weight loading it can be difficult to ensure strong cohesion, adhesion and maintain printability of the phosphor ink. For weight loadings below about 40% it is found that five or more print passes may be necessary to achieve a required phosphor material per unit area. It is to be noted that in phosphor inks 132 of the invention the weight loading of phosphor material to binder material is much higher that weight loading of pigment in a conventional screen print ink. The phosphor material comprises particles with an average particle size of 10 μm to 20 μm and typically of order 15 μm.

The viscosity of the phosphor ink 132 is primarily determined by the viscosity of the binder material and weight loading of phosphor/light reflective material. The binder material preferably has a viscosity in a range 1 Pa·s to 2.5 Pa·S (1000 to 2500 cps) Thinning additives can be used during initial formulation of the phosphor ink to achieve a required viscosity and to “thin” the phosphor ink during printing. However care must exercised when thinning to maintain the solids loading since it is the phosphor material content (loading) and layer thickness, not viscosity, that determines the color of light generated by the phosphor ink.

As well as viscosity the surface tension of the binder material can affect the phosphor ink's 132 performance. For example if the surface tension of the phosphor ink is too high, bubbles can form during printing resulting in poor layer formation. Bubbles can also form in phosphor inks with a low surface tension and it is preferred to additionally add a de-foaming agent to the phosphor ink.

### Formation of Domed Shaped Features:

The dome shaped features 120 are then formed on the wavelength conversion component by a process of thermal vacuum forming.

The carrier sheet 126 including the pattern of printed phosphor ink is carefully positioned over a former 136 comprising a plurality of dome shaped (generally hemispherical) formers 138 (FIG. 6h). As shown in FIG. 6h the carrier sheet 126 is preferably placed in the vacuum former with the pattern of printed phosphor facing the formers 138 to ensure that the wavelength conversion layer 122 will, in the finished wavelength conversion component, be on the inner concave surface of the domed feature 120. The carrier sheet 126 is aligned over the former such that each of the phosphor regions overlays a corresponding former 138. The carrier sheet 126 is then softened by heating the sheet using for example a radiant heater. Once the carrier sheet 126 is softened air between the sheet 126 and former 136 is evacuated thereby causing the sheet to conform to the former 136. The carrier sheet 126 is then cooled to re-harden the sheet (FIG. 6i) and the molded sheet removed from the vacuum molder (FIG. 5j). Finally the sheet 126 is divided into individual wavelength conversion components 104.

Assembly of Device (FIGS. 5l to 5n)

Final assembly of the device involves mounting the wavelength conversion component 104 to the light engine 102. An example of one method of mounting the wavelength conversion component 104 using a light transmissive adhesive 124 is illustrated in FIGS. 5l and 5n.

With the wavelength conversion component oriented such its base is uppermost each of the domes 120 is filled with the light transmissive adhesive 124 by for example drawing the adhesive over the base using a flexible blade (squeegee) 132. The light engine 102 (i.e. substrate 108 populated with the LED chips 106) is then brought into engagement with the wavelength conversion component such that each LED chip 106 is located within a respective dome 120 and any excess adhesive 124 removed.

In other arrangements the wavelength conversion component 104 can be bonded or otherwise attached to the light engine 102 without filling the dome shaped features with a light transmissive material.

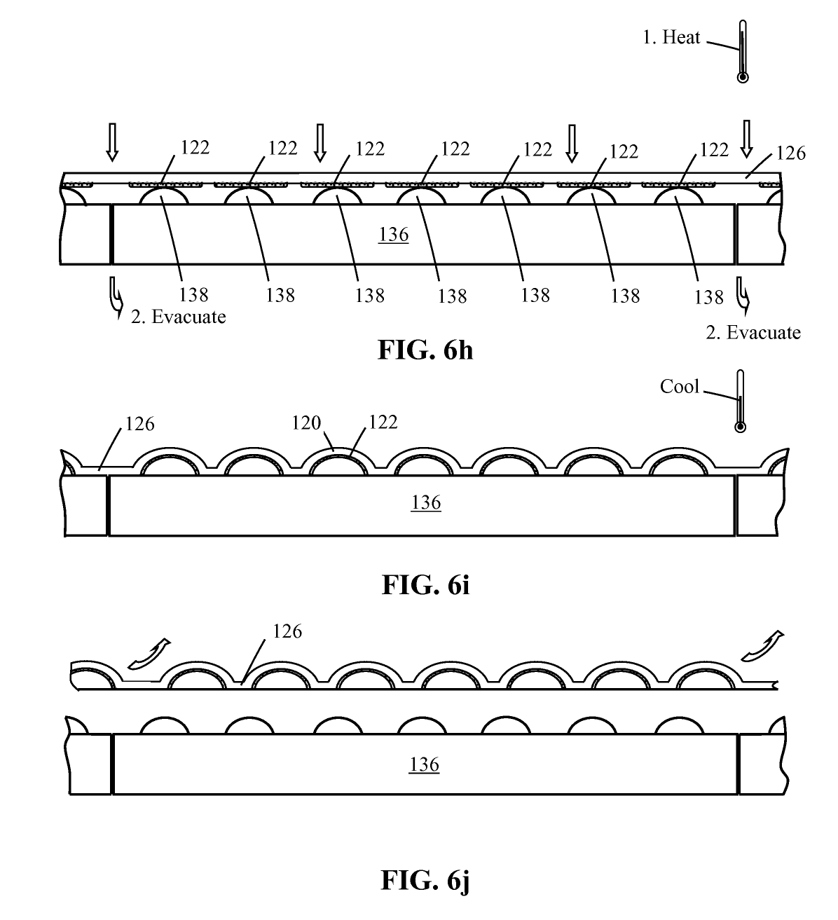

In yet other embodiments it is envisioned to fill the domes 120 using one or more channels or ports 140 that can be formed in the base of the wavelength conversion component during vacuum forming. An example of such a channel is shown in FIG. 7 which shows schematic plan, sectional and end views of a phosphor wavelength conversion component 104 in accordance with an embodiment of the invention. In this example the filling port 140 comprises a channel comprises that runs the length of the wavelength conversion component 104 and connects each of the dome shaped features 120. With the wavelength conversion component 104 positioned on the light engine 102 each of the dome shaped features can be filled with a light transmissive adhesive using the channel 140. Alternatively the wavelength conversion component 104 can be bonded to light engine 102 as described with reference to FIGS. 5l to 5n in which case the channel 140 aids in the escape of excess adhesive.

Light Emitting Devices in Accordance with Further Embodiments of the Invention

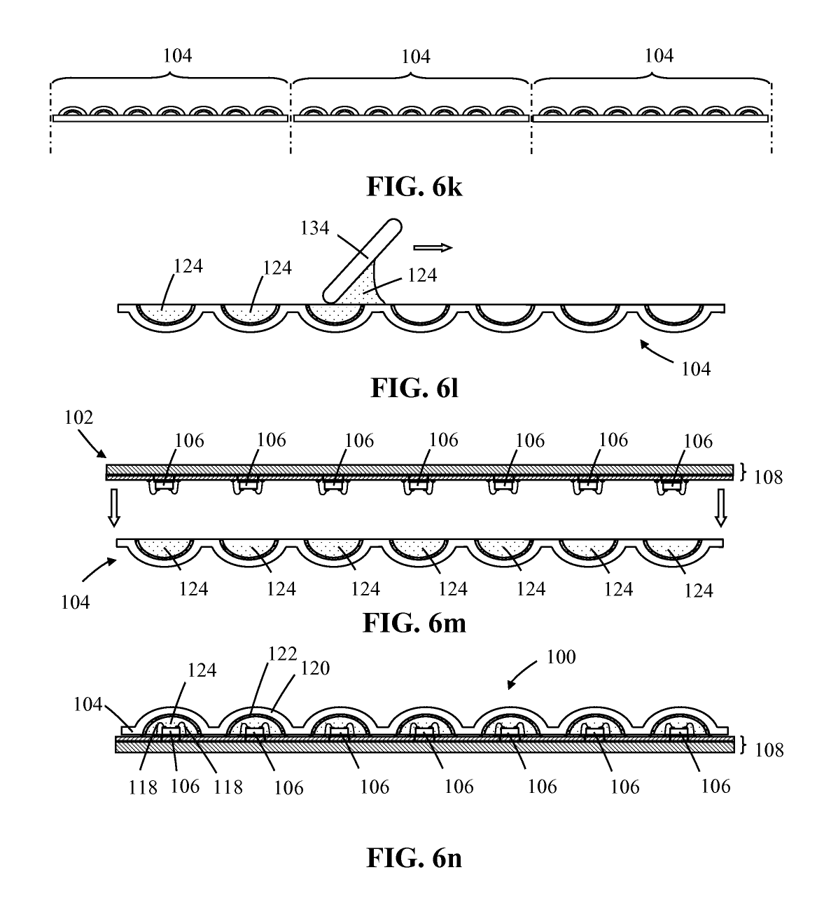

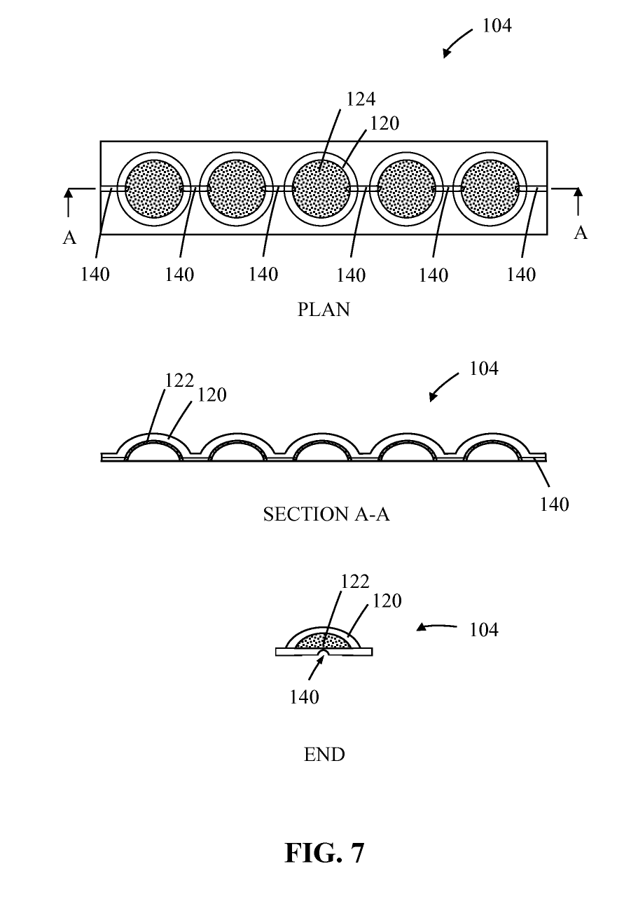

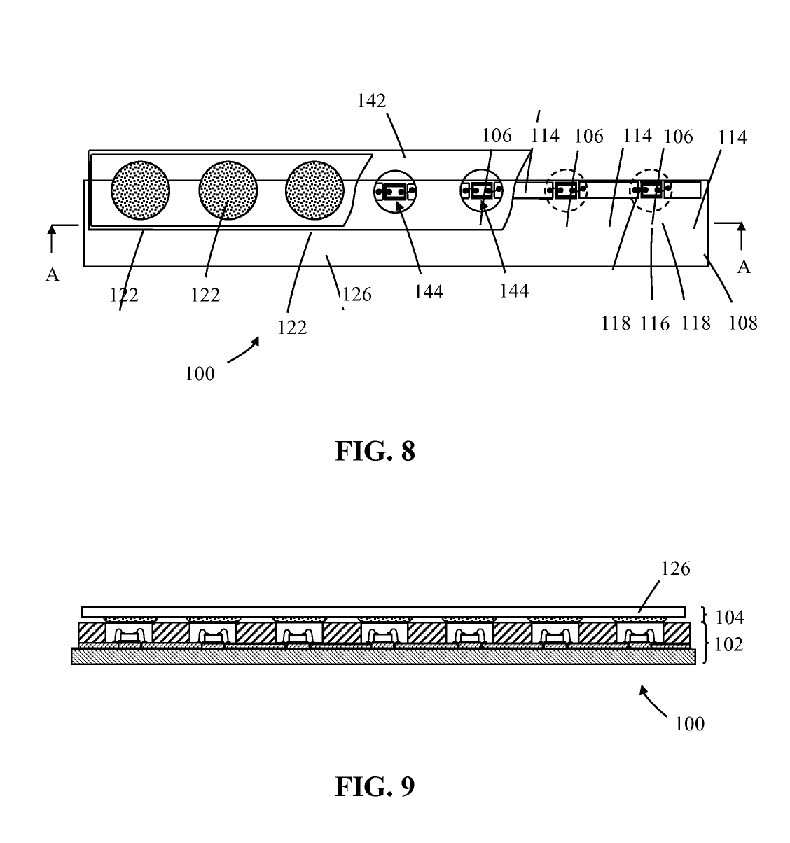

A low-cost LED-based light emitting device 100 in accordance with an embodiment of the invention is now described with reference to FIGS. 8, 9 and 10 which respectively show a schematic partial cutaway plan view, a sectional view through A-A and an exploded sectional view of the device. In common with the earlier embodiments the device 100 comprise an assembly composed of a light engine 102 and a photo luminescent wavelength conversion component 104. The light engine 102 can comprise COB arrangement comprising a plurality of blue emitting InGaN/GaN (indium gallium nitride/gallium nitride) based LED chips 106 that are mounted in a known configuration on a planar substrate 108 such as for example an MCPCB. In this embodiment the light engine further comprises a plate 142 having an array of through holes 144 in which each hole 144 corresponds with one of the LED chips. The plate can comprise any opaque material to prevent light escaping from the device such as for example a printed circuit board, a glass fiber reinforced board, a ceramic plate, a metal plate or a plastics material. The holes 144 are configured such that when the plate 142 is mounted to the substrate 108 each hole 144 in conjunction with the substrate 108 defines a shallow cavity that surrounds a respective LED chip 106. The thickness of the plate 142 is selected such that when the plate is mounted to the substrate the plate's upper surface is level or above the uppermost surface of the LED chip/bond wires. Since the plate 142 provides a spacing of the wavelength conversion component this eliminates the need for molding the dome shaped features 122. For such devices therefore the wavelength conversion component 104 can comprise a substantially planar light transmissive substrate 126 having an array of screen printed phosphor regions and can be manufactured using the method of FIGS. 6d to 6g. Since there is no need to mold substrate 126 it can comprise any light transmissive material such as a light transmissive polymer or a glass. As is best seen in FIG. 10 the wavelength conversion component 104 can be mounted to the plate 142 such that each phosphor region 124 overlays and covers a respective opening 144. A particular benefit of such devices is the low-cost production of the phosphor wavelength component.

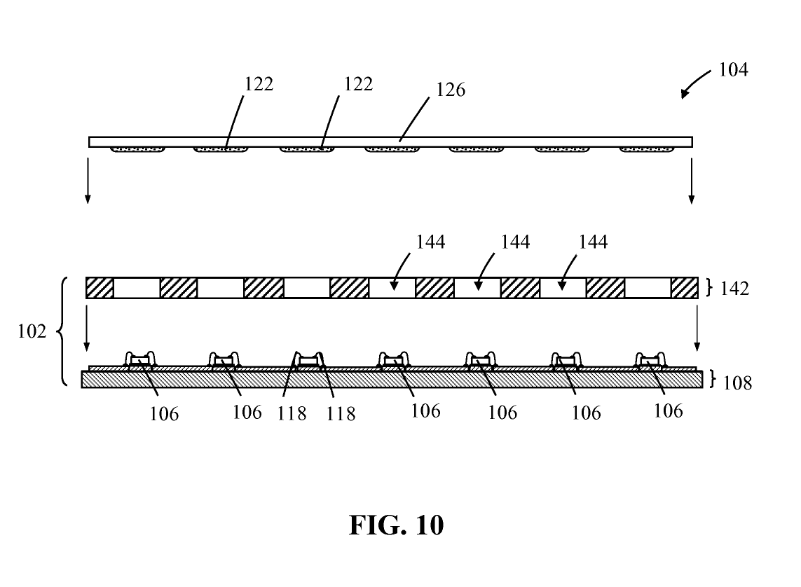

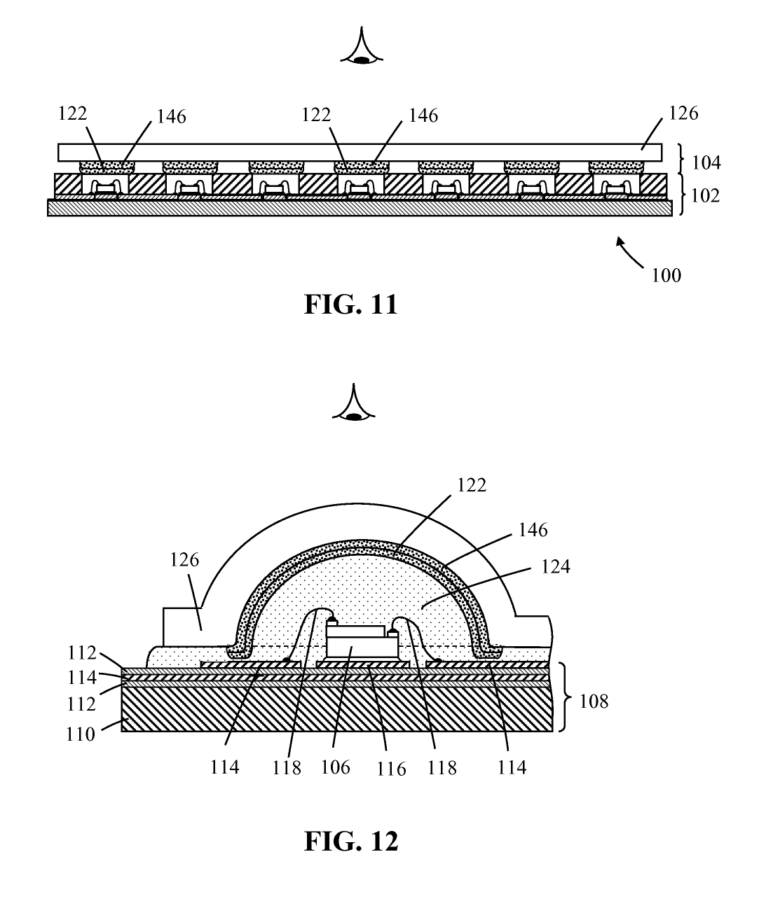

FIGS. 11 and 12 show solid-state based light emitting devices in accordance with embodiments of the invention. In these embodiments, the photo luminescent wavelength conversion component further comprises a layer of a white colored light diffusive material 146. The light diffusive material may be used for aesthetic considerations and to improve the visual appearance of the device in an “OFF-state”, that is its OFF-state white appearance. One issue with light emitting devices that utilize photo luminescent wavelength conversion is the non-white color appearance of the device in its OFF-state. During the ON-state of the device, the LED chips generate blue light and the phosphor(s) absorbs a percentage of the blue light and re-emits yellow light or a combination of green and red light, green and yellow light, green and orange, or yellow and red light. The portion of the blue light generated by the LED that is not absorbed by the phosphor combined with the light emitted by the phosphor provides light which appears to the human eye as being nearly white in color. However, for a device in its OFF-state, the absence of the blue light that would otherwise be produced by the LED in the ON-state causes the device, in particular the wavelength conversion component, to have a yellowish, yellow-orange, or orange-color appearance. This non-white appearance may be off-putting or undesirable to the potential purchasers and hence cause loss of sales to target customers. In the current embodiments and to improve the OFF-state, the photo luminescent wavelength conversion layer 122, as viewed from the exterior of the device, is masked by a layer of white light diffusive material 146.

The light diffusive material layer can comprise a mixture of a light transmissive binder and particles of a light diffusive material such as titanium dioxide (TiO₂). The light diffusive material can be deposited on the carrier in a like fashion as the photo luminescent material and is preferably screen printed. The light diffusive material can also other materials such as barium sulfate (BaSO₄), magnesium oxide (MgO), silicon dioxide (SiO₂) or aluminum oxide (Al₂O₃). Typically the light diffusive material is white in color. In this way, in an off-state, the phosphor material within the wavelength conversion component will appear white in color instead of the phosphor material color which is typically yellow-green, yellow or orange in color. In alternative embodiments the light diffusive material can be provided over the entire surface of the carrier or alternatively incorporated within the carrier such that it is homogeneously distributed throughout the volume of the substrate.

It will be appreciated that the invention is not limited to the exemplary embodiments described and that variations can be made within the scope of the invention. For example whilst the invention arose in relation to LED-based light emitting devices other embodiments can be based on other solid-state (semiconductor) light emitters such as electroluminescent emitters including but not limited to laser diodes and lasers.

What is claimed is:

1. A method of manufacturing a solid-state light emitting device comprising:
a) providing a substrate and a plurality of solid-state light emitters;
b) mounting and electrically connecting the light emitters on the substrate in a known configuration;
c) providing a light transmissive carrier;
d) screen printing a pattern of at least one photo luminescent material onto a surface of the carrier such that there is a respective region of the at least one photo luminescent material corresponding to a respective one of the light emitters;
e) positioning the carrier on the substrate such that each photo luminescent material region overlays a respective one of the light emitters.

2. The method of claim 1, wherein the known configuration of the light emitters is selected from the group consisting of: a linear array, a square array, a rectangular array, a hexagonal array and a circular array.

3. The method of claim 1, and further comprising:
f) providing a plate having an array of through holes and wherein the array of through holes corresponds to the known array of light emitters;
g) positioning the plate on the substrate such that each light emitter is housed within a respective through hole; and
h) positioning the carrier to the plate such that each region of photo luminescent material overlays a respective one of the through holes.

4. The method of claim 1, wherein the light transmissive carrier is selected from the group consisting of: a light transmissive polymer, a polycarbonate, an acrylic, a polyethylene terephthalate and a glass.

5. The method of claim 1, wherein the light transmissive carrier is a thermo formable material and further comprising:
i) heating and vacuum molding the carrier such as to form an array of hollow features configured such that a respective feature corresponds to a respective light emitter and is capable of housing a respective light emitter; and
j) in e) positioning the carrier on the substrate such that each light emitter is housed within a hollow feature.

6. The method of claim 5, and comprising in d) printing the respective regions of the at least one photo luminescent material such that when the features are vacuum molded the phosphor material covers substantially the inner surface of the feature.

7. The method of claim 5, wherein the hollow features are selected from the group consisting of being: dome shaped, a substantially hemispherical shell, a parabloidal shell and a cylindrical shell.

8. The method of claim 5, and further comprising filing each hollow feature with a light transmissive material.

9. The method of claim 5, wherein the thermoplastic material is selected from the group consisting of: a polycarbonate, an acrylic and a Polyethylene terephthalate.

10. The method of claim 1, and comprising electrically connecting the light emitters to the substrate by wire bonding.

11. The method of claim 1, and comprising in b) mounting and electrically connecting the light emitters to the substrate by flip chip bonding.

12. The method of claim 1, wherein the substrate is selected from the group consisting of: a metal cored printed circuit board, a fire retardant printed circuit board and a ceramic circuit board.

13. The method of claim 1, wherein the at least one photo luminescent material comprises a phosphor material.

14. A method of manufacturing a wavelength conversion component for a light emitting device of a type comprising a plurality of solid-state light emitters mounted on a substrate in a known configuration; the method comprising:
a) providing a light transmissive carrier; and
b) screen printing a pattern of at least one photo luminescent material onto a surface of the carrier such that there is a respective region of photo luminescent material corresponding to a respective one of the light emitters.

15. The method of claim 14, wherein the light transmissive carrier is selected from the group consisting of: a light transmissive polymer, a polycarbonate, an acrylic, a polyethylene terephthalate and a glass.

16. The method of claim 14, wherein the light transmissive carrier is a thermo formable material and further comprising:
c) heating and vacuum molding the carrier such as to form an array of hollow features configured such that there is a respective feature corresponding to a respective light emitter and each featured is capable of housing a respective light emitter.

17. The method of claim 16, wherein the light transmissive carrier is selected from the group consisting of: a polycarbonate, an acrylic and a polyethylene terephthalate.

18. The method of claim 14, and comprising manufacturing a plurality of wavelength conversion components on a sheet and dividing the sheet into separate components.

19. The method of claim 16, and comprising in b) printing the respective regions of the at least one photo luminescent material such that when the features are vacuum molded the photo luminescent material covers substantially the inner surface of the feature.

20. The method of claim 16, wherein the hollow features are selected from the group consisting of being: dome shaped, a substantially hemispherical shell, a parabloidal shell and a cylindrical shell.

21. The method of claim 14, wherein the pattern of photo luminescent material regions is selected from the group consisting of: a linear array, a square array, a rectangular array, a hexagonal array and a circular array.

22. A light emitting device comprising:
a substrate;
a plurality of solid-state light emitters mounted on, and electrically connected to, the substrate in a known configuration; and
a wavelength conversion component comprising at least one photo luminescent material and operable to absorb a portion of light emitted by the light emitters and emit light of a different wavelength, wherein the emission product of the device comprises a combination of light generated by the light emitters and the at least one photo luminescent material, and wherein the wavelength conversion component comprises a light transmissive carrier having a pattern of the at least one photo luminescent material on a surface of the carrier and configured such that there is a respective region of photo luminescent material corresponding to a respective one of the light emitters.

23. The device of claim 22, and further comprising a plate having an array of through holes that are configured as the known array and are capable of housing a respective light emitter and wherein the wavelength conversion component is positioned on the plate such that each photo luminescent material region overlays a respective one of the through holes.

24. The device of claim 22 and further comprising an array of hollow features molded in the carrier and configured such that a respective feature corresponds to a respective light emitter and is capable of housing a respective light emitter.

25. The device of claim 24, wherein a respective region of the at least one photo luminescent material covers substantially the inner surface of respective feature.

26. The device of claim 22, wherein the hollow features are selected from the group consisting of being: dome shaped, a substantially hemispherical shell, a parabloidal shell and a cylindrical shell.

27. The device of claim 22, wherein the known configuration of light emitters is selected from the group consisting of: a linear array, a square array, a rectangular array, a hexagonal array and a circular array.

28. The device of claim 22, wherein the light emitters are electrically connected to the substrate by wire bonding.

29. The device of claim 22, wherein the light emitters are mounted on, and electrically connected to, the substrate using flip chip bonding.

30. The device of claim 22, wherein the light transmissive carrier is selected from the group consisting of: a light transmissive polymer, a polycarbonate, an acrylic, a polyethylene terephthalate and a glass.

31. The device of claim 22, wherein the substrate is selected from the group consisting of: a metal cored printed circuit board, a fire retardant printed circuit board and a ceramic circuit board.

32. A wavelength conversion component for a light emitting device of a type comprising a plurality of solid-state light emitters mounted on a substrate in a known configuration; the component comprising:
a) a light transmissive carrier; and
b) a pattern of at least one photo luminescent material screen printed onto a surface of the carrier such that there is a respective region of photo luminescent material corresponding to a respective one of the light emitters.

33. The component of claim 32, and further comprising an array of hollow features molded into the carrier and configured such that a respective feature corresponds to a respective light emitter and is capable of housing a respective light emitter.
